(19) United States
(12) Patent Application Publication
(10) Pub. No.: US 2008/0315337 A1
(43) Pub. Date: Dec. 25, 2008

(54) Light receiving element

(75) Inventor: Akihiro Hasegawa, Hashima-shi (JP)

Correspondence Address: OLIFF & BERRIDGE, PLC, P.O. BOX 320850, ALEXANDRIA, VA, 22320-4850, US

(73) Assignees: SANYO ELECTRIC CO., LTD., Moriguchi-shi (JP); SANYO SEMICONDUCTOR CO., LTD., Ora-gun (JP)

(21) Appl. No.: 12/076,509

(22) Filed: Mar. 19, 2008

(30) Foreign Application Priority Data
Mar. 30, 2007 (JP) 2007-092666

(51) Int. Cl. H01L 31/00

(52) U.S. Cl. 257/431; 257/E31.001

(57) ABSTRACT

There is provided a structure for a light receiving element having a plurality of light receiving regions, whereby noise charges from a light receiving region can be prevented from becoming superimposed on the signal charges of another light receiving region so that the light receiving regions can generate accurate electric current signals. The structure includes a first light receiving region and a second light receiving region formed on a semiconductor substrate, and a selection circuit connected to the first and second light receiving regions. Each light receiving region has at least one light receiving unit that is divided into a plurality of segments and that outputs current signals in response to incident light. The selection circuit selectively outputs the current signals from either the first light receiving region or the second light receiving region, and which connects the other to a predetermined potential.

### CROSS-REFERENCE TO RELATED APPLICATION

The priority application number JP2007-092666 upon which this patent application is based is hereby incorporated by the reference.

### BACKGROUND OF THE INVENTION

1. Field of the Invention

The present invention relates to a light receiving element provided with a plurality of light receiving regions having light receiving units which are divided into a plurality of segments.

2. Description of the Related Art

FIG. 1 shows a flat surface configuration of a conventional light receiving element 170. The light receiving 170 has a first light receiving region 72 and a second light receiving region 78. The first light receiving region 72 is composed of a first light receiving unit 72-1, and the second light receiving region 78 is composed of a second light receiving unit 78-1. The first light receiving unit 72-1 and the second light receiving unit 78-1 each have a configuration which includes four PIN photodiodes (PD) 76-1, 76-2, 76-3, and 76-4. The structure of each of these light receiving units is disclosed in Japanese Laid-open Patent Application No. 2006-332104. Electric current signals obtained from the PDs 76 are output to a selection circuit 210.

The configuration of the selection circuit 210 includes eight transistors 211-1, 211-3, 212-1, 212-3, 213-1, 213-3, 214-1, and 214-3. On the basis of a control signal CTL, the selection circuit 210 selectively outputs either the electric current signals generated by the first light receiving region 72 or those by the second light receiving region 78. For example, where the electric current signals of the first light receiving region 72 are to be output, the selection circuit 210 will place the transistors 211-1, 212-1, 213-1, and 214-1 in the On state on the basis of the control signal CTL. Or, where the electric current signals of the second light receiving region 78 are to be output, the selection circuit 210 will place the transistors 211-3, 212-3, 213-3, and 214-3 in the On state on the basis of the control signal CTL.

FIG. 2 shows a detailed plan view of an example of the first light receiving unit 72-1. The configuration of the second light receiving unit 78-1 is similar to the configuration of the first light receiving unit 72-1 shown in FIG. 2.

PDs 76-1, 76-2, 76-3, and 76-4 are separated by a separation region 80 which is formed about their perimeters, on the surface of the semiconductor substrate. For example, a p⁺ region, in which high concentration of p-type impurities has been dispersed, is formed as the separation region 80. In the areas of the silicon substrate which correspond to the light receiving units, electrons and electron holes are generated through absorption of light. A cathode region 82 for collecting the electrons from among the charges so generated is arranged in each PD 76. For example, an n⁺ region, in which a high concentration of n-type impurities is dispersed, is formed as the cathode region 82.

The cathode regions 82 are connected via contacts to lines 86 which have been formed by an Al layer, for example. Ground potential is applied to the separation region 80 through lines 84 which extend from adjacent regions, for example. Signal charges collected by the cathode regions 82 are read out to the selection circuit 210 via the lines 86. For example, an electric current signal read out from a cathode region 82 and output from the selection circuit 210 will be converted to a voltage signal by an electric current detector, and then amplified by an amplifier circuit.

FIG. 3 shows a typical cross-sectional view of the structure of the light receiving element 170 in a vertical cross section of the semiconductor substrate taken along the line A-A′ shown respectively in FIG. 1 and FIG. 2. This cross section depicts the structures of the PDs 76-2 and 76-4 of the first light receiving unit 72-1; of the PDs 76-2 and 76-4 of the second light receiving unit 78-1; of the lines and interlayer insulating film layers deposited on the semiconductor substrate on which these have been formed, and so on.

The light receiving element 170 is formed using a semiconductor substrate on which an epitaxial layer 92, having a lower impurity concentration and a higher resistivity than a P-sub layer 90, is layered on the P-sub layer 90, which is a p-type silicon substrate into which p-type impurities have been introduced. The P-sub layer 90 constitutes a shared anode for the PDs 76; ground potential is applied from the back face of the substrate, for example. As noted above, through the lines 84 which have been provided on the back face of the substrate ground potential is applied to the separation region 80, which together with the P-sub layer 90 constitutes the anode.

The epitaxial layer 92 constitutes the i-layer of the PDs 76 first light receiving unit 72-1 and of the second light receiving unit 78-1. The low-concentration impurities introduced into the epitaxial layer 92 are p-type impurities, for example. The thickness of the epitaxial layer 92 will be equal to or greater than the absorption length in the semiconductor, of the light that is to be detected. For example, the absorption length of silicon with respect to light in the 780 nm band or 650 nm band used for CDs and DVDs is between about 10 and 20 μm. Accordingly, in this case the epitaxial layer 92 thickness will be set to between about 10 and 20 μm. In the first light receiving unit 72-1 and the second light receiving unit 78-1, the separation region 80 and the cathode regions 82 mentioned above are formed on the surface of the epitaxial layer 92.

After the PD 76 structure has been formed on the surface of the semiconductor substrate in the manner described above, the line structure, a passivation layer, and so on will be formed on the semiconductor substrate. By way of example, an antireflective film 126 may be deposited on the substrate surface, a first interlayer insulating film 130 then deposited, a line layer 132 composed of metal film then deposited, and a second interlayer insulating film 136 then deposited. The lines 86 shown in FIG. 2 are formed by the line layer 132, for example.

The light receiving element 170 may be used in an optical pickup for the recording and playback of DVDs, CDs, and other optical discs. The first and second light receiving regions 72 and 78 receive light reflected from laser light outputted from the optical pickup and generate electric current signals. The electric current signals generated by the first and second main light receiving units 72-1 and 78-1 are inputted to a signal processing circuit. The signal processing circuit performs demodulation processing and decoding processing, and plays back digital data from the inputted electric current signals. The electric current signals generated by the first and second light receiving units 72-1, 78-1 are also used to control the operation of the optical pickup. Specifically, a tracking error signal is generated from the electric current signals generated by the first and second light receiving units 72-1 and 78-1. An optical disc recording/playback apparatus provided with an optical pickup controls the optical pickup so that it follows the recorded track formed on the optical disk, on the basis of the tracking error signal.

The first light receiving region 72 and the second light receiving region 78 are provided for recording and playing back two mutually different types of optical discs. For example, the first light receiving region 72 is provided for recording and playing back DVDs, and the second light receiving region 78 is provided for recording and playing back CDs. Reflected light of the laser light will be incident on the first light receiving region 72 during recording and playback of a DVD, and reflected light of the laser light will be incident on the second light receiving region 78 during recording and playback of a CD.

The first light receiving region 72 and the second light receiving region 78 provided to the light receiving element 170 receive reflected light of the laser light via an optical lens, which is not shown. For example, reflected light of the laser light will be received by the first light receiving region 72 during recording and playback of a DVD. At this time, due to the effects of dispersion of light by the optical lens and the like, the reflected light will be incident not only on the first light receiving region 72 but also on the second light receiving region 78, and signal charges will be generated.

Because the first light receiving region 72 and the second light receiving region 78 are separated by the separation region 80, the signal charges generated in the second light receiving region 78 will basically be held in the second light receiving region 78. However, because the second light receiving region 78 is in a floating state when the first light receiving region 72 is operated and the reflected light of the laser is received, part of the signal charges generated in the second light receiving region 78 will occasionally cross over the separation region 80. For example, part of the signal charges generated by the PDs 76-1 and 76-2 which are included in the second light receiving region 78 may cross over the separation region 80 and move to the PDs 76-3 and 76-4 which are included in the first light receiving region 72, becoming superimposed as noise charges on the signal charges of these PDs 76-3 and 76-4. At this time, the PDs 76-3 and 76-4 included in the first light receiving region 72 will output electric current signals on the basis of the sum of the signal charges generated in the first light receiving region 72, and the noise charges generated in the second light receiving region 78.

For the reason described above, the PDs 76-3 and 76-4 which are included in the first light receiving region are more susceptible to the effects of noise charges in comparison with the PDs 76-1 and 76-2 which are included in the first light receiving region 72. This can result in the problem of inaccurate control of the optical pickup carried out on the basis of the electric current signals output by the first light receiving region 72. Also, there is a similar problem when the second light receiving region 78 is used.

### SUMMARY OF THE INVENTION

In view of the above-described prior art, it is an object of the present invention to provide a light receiving element which, even where provided with a plurality of light receiving regions, can prevent the superimposition of noise charges and generate accurate electric current signals.

The present invention comprises a first light receiving region, which is formed on a semiconductor substrate, and which has at least one light receiving unit that is divided into a plurality of segments and that outputs electric current signals in response to incident light; a second light receiving region, which is formed on the semiconductor substrate, and which has at least one light receiving unit that is divided into a plurality of segments and that outputs electric current signals in response to incident light; and a selection circuit, which is connected to the first light receiving region and the second light receiving region, which selectively outputs the electric current signals from either the first light receiving region or the second light receiving region, and which connects the other to a predetermined potential.

### BRIEF DESCRIPTION OF THE DRAWINGS

FIG. 1 is a schematic plan view of a conventional light receiving element;

FIG. 2 is a plan view of a conventional first light receiving unit;

FIG. 3 is a schematic sectional view depicting the structure of a conventional light receiving element;

FIG. 4 is a schematic plan view of a light receiving element in an embodiment of the present invention; and

FIG. 5 is a schematic plan view of a light receiving element in another embodiment of the present invention.

### DESCRIPTION OF THE PREFERRED EMBODIMENTS

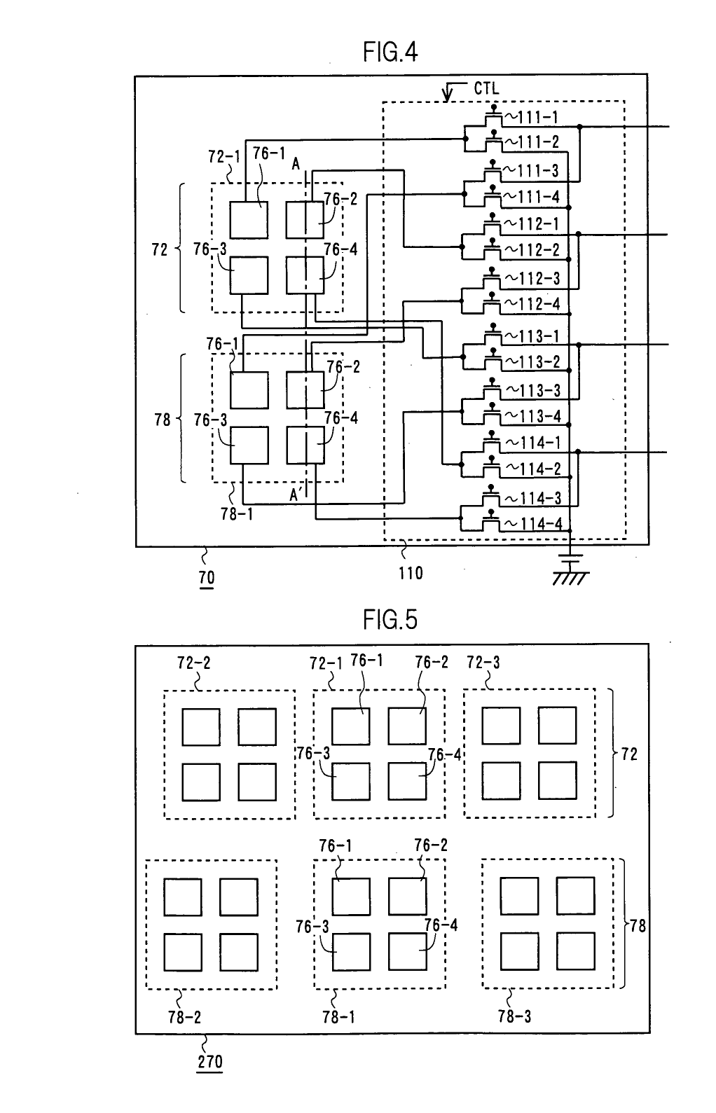

FIG. 4 is a schematic plan view of the light receiving element of an embodiment of the present invention. The light receiving element 70 is formed on a semiconductor substrate composed of silicon, and is configured to include a first light receiving region 72 and a second light receiving region 78.

The first light receiving region 72 includes, for example, a first light receiving unit 72-1 having four PIN photodiodes (PD) 76 in a 2×2 array, and light that has been emitted from an optical system and has impinged on the substrate surface is divided into four, i.e. 2×2, segments and received. A second light receiving region 78 similar to the first light receiving region 72 includes a second light receiving unit 78-1 having four PDs 76. Electric current signals generated by the first light receiving unit 72-1 and the second light receiving unit 78-1 are respectively output to a selection circuit 110.

The selection circuit 110 configuration includes 16 transistors 111-1, 111-2, 111-3, 111-4, 112-1, 112-2, 112-3, 112-4, 113-1, 113-2, 113-3, 113-4, 114-1, 114-2, 114-3, and 114-4. On the basis of a control signal CTL, the selection circuit 110 selectively outputs the electric current signals either from the first light receiving region 72 or from the second light receiving region 78, and connects the other to a predetermined potential, such as +3 V, for example. That is, where the light receiving unit of either the first light receiving region 72 or the second light receiving region 78 is selectively operated, the PDs 76 included in the other light receiving unit will be fixed to the prescribed potential, and thus will not assume a floating state.

Where the electric current signals generated by the first light receiving region 72 are output, on the basis of the control signal CTL the selection circuit 110 will place the transistors 111-1, 111-4, 112-1, 112-4, 113-1, 113-4, 114-1, and 114-4 in the On state, and place the transistors 111-2, 111-3, 112-2, 112-3, 113-2, 113-3, 114-2, and 114-3 in the Off state. At this point, the electric current signals of the PDs 76-1, 76-2, 76-3, 76-4 included in the first light receiving unit 72-1 will be respectively output to the selection circuit 110 via the transistors 111-1, 112-1, 113-1, and 114-1. For the PDs 76-1, 76-2, 76-3, 76-4 included in the second light receiving unit 78-1, a prescribed potential will be applied via the transistors 111-4, 112-4, 113-4, and 114-4.

Where the electric current signals generated by the second light receiving region 78 are output, the selection circuit 110 will, on the basis of the control signal CTL, place the transistors 111-2, 111-3, 112-2, 112-3, 113-2, 113-3, 114-2, and 114-3 in the On state, and place the transistors 111-1, 111-4, 112-1, 112-4, 113-1, 113-4, 114-1, and 114-4 in the Off state. At this point, the electric current signals of the PDs 76-1, 76-2, 76-3, 76-4 included in the second light receiving unit 78-1 will be respectively output to the selection circuit 110 via the transistors 111-3, 112-3, 113-3, and 114-3. For the PDs 76-1, 76-2, 76-3, 76-4 included in the first light receiving unit 72-1, a prescribed potential will be applied via the transistors 111-2, 112-2, 113-2, and 114-2.

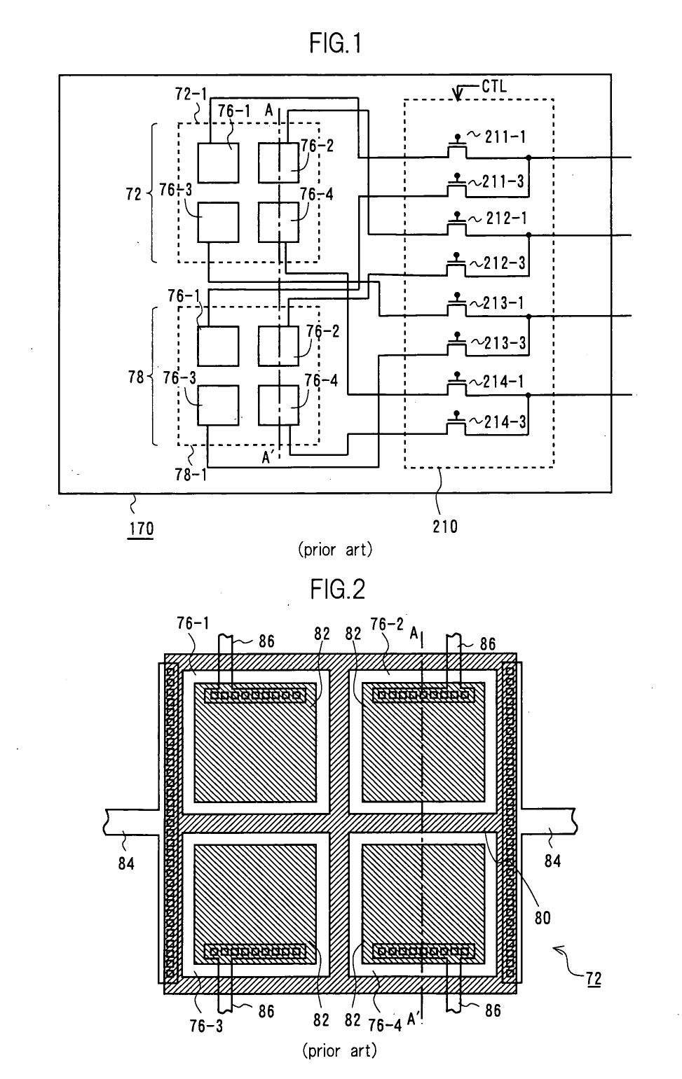

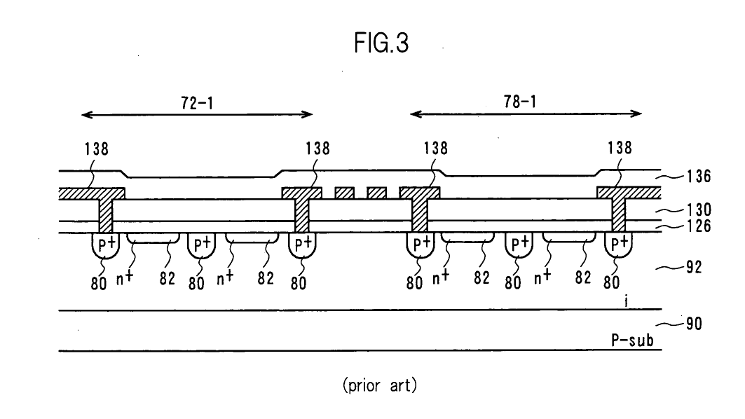

The first light receiving unit 72-1 and the second light receiving unit 78-1 in the embodiment of the present invention have detailed planar configurations which are the same as the configuration of the aforementioned prior art shown in FIG. 2. The structure of the light receiving element 70 in the embodiment of the present invention, viewed in vertical cross section of the semiconductor substrate taken along the line A-A′ as shown in FIG. 4, is the same as the structure of the aforementioned prior art shown in FIG. 3. That is, where the first light receiving unit 72 is selectively operated, the cathode region 82 included in the second light receiving region 78 will be fixed at a prescribed potential; and where the second light receiving unit 78 is selectively operated, the cathode region 82 included in the first light receiving region 72 will be fixed at a prescribed potential.

The intermediate semiconductor region recited in the Claims corresponds to the epitaxial layer 92 in the embodiment of the present invention; the lower semiconductor region corresponds to the P-sub layer 90; and the upper semiconductor region corresponds to the cathode region 82.

Like the light receiving element 170 pertaining to the prior art, the light receiving element 70 is used in an optical pickup for recording and playback of DVDs, CDs, and other optical discs. The first and second light receiving regions 72 and 78 receive light reflected from laser light outputted from the optical pickup and generate electric current signals. The electric current signals generated by the first and second light receiving units 72-1 and 78-1 are inputted to a signal processing circuit which is connected to a subsequent stage of the selection circuit 110. The signal processing circuit performs demodulation processing and decoding processing, and plays back digital data from the inputted electric current signal. The electric current signals generated by the first and second light receiving units 72-1, 78-1 are also used to control the operation of the optical pickup. Specifically, a tracking error signal is generated from the electric current signals generated by the first and second light receiving units 72-1 and 78-1. An optical disc recording/playback apparatus provided with an optical pickup controls the optical pickup so that it follows the recorded track formed on the optical disk, on the basis of the tracking error signal.

The first light receiving region 72 and the second light receiving region 78 are provided for recording and playing back two mutually different types of optical discs. For example, the first light receiving region 72 is provided for recording and playing back DVDs, and the second light receiving region 78 is provided for recording and playing back CDs. Reflected laser light will impinge on the first light receiving region 72 during recording and playback of a DVD, and reflected light of the laser light will impinge on the second light receiving region 78 during recording and playback of a CD.

For example, in the case of recording or playback of an optical disk carried out using the first light receiving region 72, the effects of light dispersed by the optical lens or the like will cause the reflected light to impinge not only on the first light receiving region 72 but also on the second light receiving region 78, and signal charges will be generated. In such instances, part of the signal charges generated in the second light receiving region 78 occasionally cross over the separation region 80 provided in the second light receiving region and move into the first light receiving region 72. In the embodiment of the present invention, however, since the cathode region 82 included in the second light receiving region 78 is fixed at a prescribed potential, the signal charges generated by the second light receiving region 78 will be emitted via the cathode region 82. Thus, it will be possible to prevent charges generated in the second light receiving region 78 from migrating to the first light receiving region 72 and becoming superimposed as noise charges on the signal charges of the first light receiving region 72; and the first light receiving region 72 will be able to generate accurate electric current signals depending on the intensity of reflected light. A similar effect can be achieved in the case of recording or playback of an optical disk carried out using the second light receiving region 78.

FIG. 5 is a schematic plan view of a light receiving element 270 in another embodiment of the present invention. The light receiving element 270 is formed on a semiconductor substrate of silicon, and has a first light receiving region 72 and a second light receiving region 78. A point of difference from the embodiment of invention shown in FIG. 4 is that the first light receiving region 72 and the second light receiving region 78 are respectively divided into a plurality of light receiving units.

The first light receiving region 72 has a first main light receiving unit 72-1 and first auxiliary light receiving units 72-2 and 72-3. The first main light receiving unit 72-1 is positioned between the first auxiliary light receiving units 72-2 and 72-3. The second light receiving region 78, like the first light receiving region 72, has a second main light receiving unit 78-1 and second auxiliary light receiving units 78-2 and 78-3, with the second main light receiving unit 78-1 disposed between the second auxiliary light receiving units 78-2 and 78-3. The interspacing between the first main light receiving unit 72-1 and the first auxiliary light receiving units 72-2 and 72-3 included in the first light receiving region 72 is smaller than the interspacing between the second main light receiving unit 78-1 and the second auxiliary light receiving units 78-2 and 78-3 included in the second light receiving region 78, for example.

The electric current signals generated by the first and second main light receiving units 72-1 and 78-1 are inputted to a signal processing circuit. The signal processing circuit performs demodulation processing and decoding processing, and plays back digital data from the inputted electric current signals. The electric current signals generated by the first and second auxiliary light receiving units 72-2, 72-3, 78-2, 78-3 are used to control the operation of the optical pickup. Specifically, a tracking error signal is generated from the output signals of the auxiliary light receiving units. An optical disc recording/playback apparatus provided with an optical pickup controls the optical pickup so that it follows the recorded track formed on the optical disk, on the basis of the tracking error signal.

The first light receiving region 72 and the second light receiving region 78 included in the light receiving element 270 are connected to a selection circuit, not shown. In the same way as in the embodiment of the invention shown in FIG. 4, where recording or playback of an optical disk is carried out using the first light receiving region 72, the selection circuit will output the electric current signals generated by the PDs 76 included in the first light receiving region 72, and a prescribed potential will be applied to the PDs 76 included in the second light receiving region 78. Meanwhile, where recording or playback of an optical disk is carried out using the second light receiving region 78, the selection circuit will output the electric current signals generated by the PDs 76 included in the second light receiving region 78, and a prescribed potential will be applied to the PDs 76 included in the first light receiving region 72.

While the embodiments of the present invention herein have a configuration wherein a ground potential is applied to the P-sub layer 90 and the separation region 80, the present invention is not limited to this particular arrangement. It would be possible to apply different potentials to the P-sub layer 90 and to the separation region 80, depending on the region.

In the embodiments of the present invention, it is preferable for the selection circuit 110 to be formed on the semiconductor substrate on which the first light receiving region 72 and the second light receiving region 78 are arranged. However, the selection circuit 110 could instead be arranged on a semiconductor substrate separate from the semiconductor substrate on which the first light receiving region 72 and the second light receiving region 78 are arranged. The control signal CTL which is input to the selection circuit 110 can be obtained from outside the light receiving element. Also, a control circuit could be formed on the semiconductor substrate on which the selection circuit 110 is formed, and a control signal CTL generated by this control circuit could be input to the selection circuit 110.

According to the present invention, it is possible to prevent the superimposition of noise charges and generation of accurate electric current signals, even where the light receiving element is provided with a plurality of light receiving regions.

What is claimed is:

1. A light receiving element comprising:
a first light receiving region, which is formed on a semiconductor substrate, and which has at least one light receiving unit that is divided into a plurality of segments and that outputs electric current signals in response to incident light;
a second light receiving region, which is formed on the semiconductor substrate, and which has at least one light receiving unit that is divided into a plurality of segments and that outputs electric current signals in response to incident light; and
a selection circuit, which is connected to the first light receiving region and the second light receiving region, which selectively outputs the electric current signals from either the first light receiving region or the second light receiving region, and which connects the other to a predetermined potential.

2. The light receiving element according to claim 1, wherein
the first light receiving region and the second light receiving region respectively include a plurality of light receiving units.

3. The light receiving element according to claim 2, wherein
the interspacing between the plurality of light receiving units included in the first light receiving region is smaller than the interspacing between the plurality of light receiving units included in the second light receiving region.

4. The light receiving element according to claim 1, wherein the light receiving unit has:
an intermediate semiconductor region having a low impurity concentration disposed on a main face of the semiconductor substrate;
a lower semiconductor region of a first conductivity having a higher impurity concentration than the intermediate semiconductor region, wherein the region is disposed in contact with a lower surface of the intermediate semiconductor region, and is impressed with a first voltage;
a separation region of a first conductivity having a higher impurity concentration than the intermediate semiconductor region, wherein the region is formed on a surface of the intermediate semiconductor region along interfaces between the segments and is impressed with a second voltage; and
a plurality of upper semiconductor regions of a second conductivity having a higher impurity concentration than the intermediate semiconductor region, wherein the regions are formed on the surface of the intermediate semiconductor region at locations respectively corresponding to the segments, and are impressed with a third voltage;
and wherein the upper semiconductor regions and the lower semiconductor region are placed in a state of inverse bias by the first and third voltages, and form a depletion layer in the intermediate semiconductor region; and the separation region forms an electric potential barrier against the migration of the signal charges between the segments to the lower semiconductor regions in accordance with the second voltage.
